(19) United States
(12) Patent Application Publication
(10) Pub. No.: US 2018/0164911 A1
(43) Pub. Date: Jun. 14, 2018

(54) CONDUCTIVE PASTE, TOUCH SENSOR MEMBER AND METHOD FOR PRODUCING CONDUCTIVE PATTERN

(71) Applicant: TORAY INDUSTRIES, INC., Tokyo (JP)

(72) Inventors: Toshiya KODAMA, Otsu-shi, Shiga (JP); Tatsuya KAJIYAMA, Otsu-shi, Shiga (JP)

(73) Assignee: TORAY INDUSTRIES, INC., Tokyo (JP)

(21) Appl. No.: 15/580,596

(22) PCT Filed: Jul. 5, 2016
(86) PCT No.: PCT/JP2016/069865

§ 371 Date: Dec. 7, 2017

(30) Foreign Application Priority Data
Jul. 10, 2015 (JP) 2015-138463

(51) Int. Cl. G06F 3/041; G03F 7/004; H01B 1/16

(52) U.S. Cl. CPC G06F 3/041; H01B 1/16; G03F 7/0047

(57) ABSTRACT

An object of the present invention is to provide a conductive paste capable of forming, at a low cost, a bridge pattern which is capable of stably securing contact resistance with a transparent electrode pattern even with a very small contact area and which is excellent in pattern accuracy, flexibility and visibility. The present invention provides a conductive paste including: (A) metal particles; (B) a tin compound; (C) a photosensitive component; and (D) a photopolymerization initiator, wherein the (B) tin compound is selected from the group consisting of indium tin oxide, antimony-doped tin oxide, phosphorus-doped tin oxide, fluorine-doped tin oxide and tin oxide, and a ratio of the (B) tin compound to a total solid is 2 to 20% by mass.

### TECHNICAL FIELD

The present invention relates to a conductive past, a touch sensor member and a method for producing a conductive pattern.

### BACKGROUND ART

In recent years, further improvement of resolution and visibility in touch position detection has been required for touch panels of smartphones and tablet terminals. As one means for meeting the requirement, a method is known in which transparent electrode patterns formed in an island shape as shown in FIGS. 1 and 2 are electrically connected to each other by a bridge pattern (Patent Documents 1 to 3). Such a bridge pattern is formed by patterning a precious metal such as gold by a sputtering method or the like.

On the other hand, a conductive paste containing inorganic particles, the surfaces of which are covered with a conductive material such as an antimony compound, is known as a material for forming a routing wiring excellent in connection stability with a transparent electrode pattern (Patent Document 4).

### PRIOR ART DOCUMENTS

### Patent Documents

Patent Document 1: Japanese Patent Laid-open Publication No. 2013-254360

Patent Document 2: Japanese Patent Laid-open Publication No. 2013-246723

Patent Document 3: Japanese Patent Laid-open Publication No. 2013-156949

Patent Document 4: WO 2013/108696

### SUMMARY OF THE INVENTION

### Problems to be Solved by the Invention

However, a bridge pattern formed using a precious metal such as gold has the problem that the production cost is increased, and visibility is deteriorated due to metallic luster.

It is also conceivable that a bridge pattern is formed using a conductive paste containing inorganic particles, the surfaces of which are covered with a conductive material as described above. However, it is required to secure contact resistance with an extremely small contact area as compared to a routing wiring. Thus, when the content of the inorganic particles, the surfaces of which are covered with a conductive material, is to be increased, the inorganic particles are aggregated, so that the patterning property and flexibility of a bridge pattern may be considerably affected.

An object of the present invention is to provide a conductive paste capable of forming, at a low cost, a bridge pattern which is capable of stably securing contact resistance with a transparent electrode pattern even with a very small contact area and which is excellent in pattern accuracy, flexibility and visibility.

### Solutions to the Problems

The present invention provides a conductive paste including: (A) metal particles; (B) a tin compound; (C) a photosensitive component; and (D) a photopolymerization initiator, wherein the (B) tin compound is selected from the group consisting of indium tin oxide, antimony-doped tin oxide, phosphorus-doped tin oxide, fluorine-doped tin oxide and tin oxide, and a ratio of the (B) tin compound to a total solid is 2 to 20% by mass.

### Effects of the Invention

According to the present invention, a bridge pattern which is excellent in pattern accuracy, flexibility and visibility and which is capable of stably securing contact resistance can be formed at a low cost.

### BRIEF DESCRIPTION OF THE DRAWINGS

FIG. 1 is a schematic view of a touch sensor member including a bridge pattern.

FIG. 2 is a schematic view showing a cross-section of the touch sensor member including the bridge pattern.

FIG. 3 is a schematic view showing a light-transmissive pattern of a photomask used for evaluation of a specific resistivity.

FIG. 4 is a schematic view showing the light-transmissive pattern of the photomask used for evaluation of the constant resistance value.

FIG. 5 is a schematic view of a member used for evaluation of a contact resistance value.

FIG. 6 is a schematic view of a member used for evaluation of flexibility.

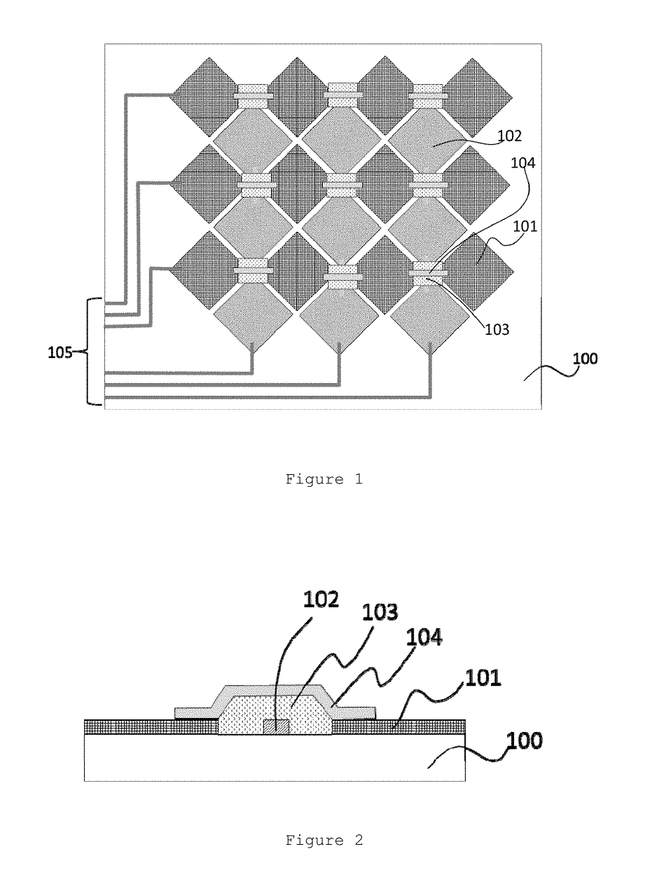

### EMBODIMENT OF THE INVENTION

A conductive paste of the present invention includes: (A) metal particles; (B) a tin compound; (C) a photosensitive component; and (D) a photopolymerization initiator, in which the tin compound (B) is selected from the group consisting of indium tin oxide, antimony-doped tin oxide, phosphorus-doped tin oxide, fluorine-doped tin oxide and tin oxide, and the ratio of the tin compound (B) to the total solid is 2 to 20% by mass.

The conductive paste of the present invention contains (A) metal particles. The (A) metal particles refer to particles each composed of a metal element. Examples of the metal particles include particles composed of silver, gold, copper, platinum, lead, tin, nickel, aluminum, tungsten, molybdenum, chromium, titanium or indium or an alloy of these metals. Particles of gold, silver or copper which have high conductivity are preferable, and silver particles which have high stability and are advantageous in terms of cost are more preferable.

The (A) metal particles have a volume average particle size of preferably 0.1 μm or more, more preferably 0.3 μm or more. The volume average particle size of the (A) metal particles is preferably 3 μm or less, more preferably 1 μm or less. When the volume average particle size of the (A) metal particles is 0.1 μm or more, the contact probability between the (A) metal particles is improved, so that the specific resistance value of the resulting conductive pattern decreases, and exposure light during exposure smoothly passes through a coating film formed from the conductive paste of the present invention. Thus, fine patterning is facilitated. On the other hand, when the volume average particle size of the (A) metal particles is 3 μm or less, the surface smoothness and dimensional accuracy of the resulting conductive pattern are improved.

The volume average particle size of the (A) metal particles can be determined by diluting the conductive paste with a solvent such as THF (tetrahydrofuran) in which a resin component is soluble; centrifugally separating the diluted conductive paste; precipitating and recovering a solid excluding the resin component; observing the recovered solid with a scanning electron microscope (SEM) or transmission electron microscope (TEM) to identify the (A) metal particles; randomly selecting 100 primary particles of the (A) metal particles; acquiring images; determining a diameter of each primary particle by image analysis with the particle assumed to have a circular shape; and calculating a volume-weighted average diameter.

The ratio of the (A) metal particles to the total solid is preferably 60% by mass or more, more preferably 70% by mass or more. In addition, the ratio of the (A) metal particles to the total solid is preferably 85% by mass or less, more preferably 80% by mass or less. When the ratio of the (A) metal particles is 60% by mass or more, the contact probability between the (A) metal particles is improved, so that the specific resistance value of the resulting conductive pattern decreases. On the other hand, when the ratio of the (A) metal particles is 85% by mass or less, exposure light during exposure smoothly passes through a coating film formed from the conductive paste of the present invention, and therefore fine patterning is facilitated. Here, the total solid refers to all constituents of the conductive paste excluding the solvent.

The ratio of the (A) metal particles to the total solid in the conductive paste of the present invention can be measured in the following manner: the conductive paste is heated at 60 to 120° C. to evaporate the solvent, the total solid is recovered, the ratio of an inorganic solid in the total solid is determined by combusting a resin component at 400 to 600° C. using a TG-DTA (differential thermal balance), the remaining inorganic solid is dissolved in nitric acid or the like, and the solution is subjected to ICP emission spectroscopic analysis to determine the ratio of the (A) metal particles in the inorganic solid.

The conductive paste of the present invention contains the (B) tin compound selected from the group consisting of indium tin oxide, antimony-doped tin oxide, phosphorus-doped tin oxide, fluorine-doped tin oxide and tin oxide in an amount of 2 to 20% by mass in terms of a ratio to the total solid. The conductive paste of the present invention contains such a tin compound in the above-mentioned certain ratio, and thus both stable reduction of contact resistance with a transparent electrode etc. and fine patterning in the resulting conductive pattern are attained without hindering contact between the (A) metal particles. The ratio of the (B) tin compound to the total solid is preferably 7 to 15% by mass.

Herein, the (B) tin compound may be present in the conductive paste as particles composed only of indium tin oxide, antimony-doped tin oxide, phosphorus-doped tin oxide, fluorine-doped tin oxide or tin oxide. In addition, the (B) tin compound may be present in a state in which the surface of a particle, a core material or the like that is composed of other compounds such as titanium oxide is attached or covered with indium tin oxide, antimony-doped tin oxide, phosphorus-doped tin oxide, fluorine-doped tin oxide or tin oxide. However, for the particle or the like which is attached or covered with the (B) tin compound, the ratio of the (B) tin compound to the total solid is determined with attention paid to only the mass of the (B) tin compound, with which the particle or the like is attached or covered, rather than the mass of the whole of the particle or the like. Among the (B) tin compounds, indium tin oxide exhibits a particularly excellent effect.

The ratio of the (B) tin compound to the total solid in the conductive paste of the present invention can be measured in the same manner as the method for determining the ratio of the (A) metal particles.

The particles of the (B) tin compound, or the particles etc. attached with the (B) tin compound have a volume average particle size of preferably 0.01 to 0.3 μm, more preferably 0.01 to 0.1 μm. When the volume average particle size of the particles of the tin compound (B) or the like is 0.01 μm or more, the contact resistance of the resulting conductive pattern is further stabilized. On the other hand, when the volume average particle size of particles of the (B) tin compound or the like is 0.3 μm or less, the contact probability between the metal particles is improved, so that the specific resistance value of the resulting conductive pattern decreases. The volume average particle size of the particles of the tin compound (B) or the like can be measured in the same manner as in the case of the volume average particle size of the (A) metal particles.

Examples of the shape of the particles of the (B) tin compound or the like include a spherical shape and an acicular shape. An acicular shape is preferable because the contact resistance of the resulting conductive pattern is effectively reduced. An aspect ratio, which is a value obtained by dividing the major axis length of an acicular particle of the (B) tin compound or the like by the minor axis length thereof, is preferably 1 to 50. The aspect ratio of the particles of the (B) tin compound or the like can be determined by observing the particles of the tin compound (B) or the like with a scanning electron microscope (SEM) or a transmission type microscope (TEM); randomly selecting 100 primary particles of the particles of the (B) tin compound or the like; measuring the major axis lengths and minor axis lengths of the primary particles, and determining the aspect ratio from the average of the major axis lengths and the average of the minor axis lengths.

The conductive paste of the present invention contains the (C) photosensitive component. The (C) photosensitive component refers to a compound having an unsaturated double bond.

Examples of the compound having an unsaturated double bond include an acryl-based monomers and acryl-based copolymers. Here, the acryl-based copolymer refers to a copolymer containing an acryl-based monomer as a copolymer component thereof.

Examples of the acryl-based Monomer include methyl acrylate, ethyl acrylate (hereinafter, referred to “EA”), acrylic acid (hereinafter, referred to as “AA”), 2-ethylhexyl acrylate, n-butyl acrylate (hereinafter, referred to as “BA”), i-butyl acrylate, i-propane acrylate, glycidyl acrylate, N-methoxymethyl acrylamide, N-ethoxymethyl acrylamide, N-n-butoxymethyl acrylamide, N-isobutoxymethyl acrylamide, butoxytriethylene glycol acrylate, dicyclopentanyl acrylate, dicyclopentenyl acrylate, 2-hydroxyethyl acrylate, isobonyl acrylate, 2-hydroxypropyl acrylate, isodexyl acrylate, isooctyl acrylate, lauryl acrylate, 2-methoxyethyl acrylate, methoxyethylene glycol acrylate, methoxydiethylene glycol acrylate, octafluoropentyl, acrylate, phenoxyethyl acrylate, stearyl acrylate, trifluoroethyl acrylate, acrylamide, aminoethyl acrylate, phenyl acrylate, phenoxyethyl acrylate, 1-naphthyl acrylate, 2-naphthyl acrylate, thiophenol acrylate, benzyl mercaptan acrylate, allylated cyclohexyl diacrylate, 1,4-butanediol diacrylate, 1,3-butylene glycol diacrylate, ethylene glycol diacrylate, diethylene glycol diacrylate, triethylene glycol diacrylate, polyethylene glycol diacrylate, dipentaerythritol hexaacrylate, dipentaerythritol monohydroxypentaacrylate, ditrimethylolpropane tetraacrylate, glycerol diacrylate, methoxylated cyclohexyl diacrylate, neopentyl glycol diacrylate, propylene glycol diacrylate, polypropylene glycol diacrylate, triglycerol diacrylate, trimethylolpropane triacrylate, bisphenol A diacrylate, bisphenol F diacrylate, diacrylates of bisphenol A-ethylene oxide adducts, diacrylates of bisphenol F-ethylene oxide adducts and diacrylates of bisphenol A-propylene oxide adducts, and compounds in which the acrylic group of these compounds is replaced by a methacrylic group.

Examples of other copolymer components include styrenes such as styrene (hereinafter, referred to as “St”), p-methylstyrene, o-methylstyrene, m-methylstyrene, α-methylstyrene, chloromethylstyrene and hydroxymethylstyrene; γ-methacryloxypropyltrimethoxysilane; and 1-vinyl-2-pyrrolidone.

By including an unsaturated acid such as an unsaturated carboxylic acid as a copolymer component, an alkali-soluble acryl-based copolymer having a carboxyl group or the like is obtained. Examples of the unsaturated acid include AA, methacrylic acid, itaconic acid, crotonic acid, maleic acid, fumaric acid and vinyl acetic acetate, and acid anhydrides thereof. The acid value of the resulting acryl-based copolymer can be adjusted by increasing or reducing the amount of the unsaturated acid to be used as a copolymer component.

By reacting a part of the unsaturated acid of the acryl-based copolymer with a compound having both a reactive group with an unsaturated acid such as glycidyl methacrylate and an unsaturated double bond, an acryl-based copolymer having a reactive unsaturated double bond on the side chain can be obtained.

The (C) photosensitive component contained in the conductive paste of the present invention has an acid value of preferably 30 to 250 mg KOH/g for obtaining moderate alkali solubility. The acid value can be measured in accordance with JIS-K0070 (1992).

When the conductive paste of the present invention contains an acryl-based copolymer and an acryl-based monomer as the (C) photosensitive component, the content of the acryl-based monomer based on 100 parts by mass of the acryl-based copolymer is preferably 1 to 100 parts by mass. When the content of the acryl-based monomer is 1 part by mass or more, the crosslinking density after exposure is stable, so that the line width can be stabilized. When the content of the acryl-based monomer is 100 parts by mass or less, the crosslinking density after exposure is not excessively high, and thus a situation can be prevented in which curing shrinkage in a curing step is insufficient and conductivity cannot be obtained.

The conductive paste of the present invention contains the (D) photopolymerization initiator. The (D) photopolymerization initiator refers to a compound which is decomposed by absorbing light having a short wavelength such as an ultraviolet ray, or which causes a hydrogen extraction reaction to generate a radical.

Examples of the (D) photopolymerization initiator include 1,2-octanedione, 1-[4-(phenylthio)-2-(O-benzoyloxime)], 2,4,6-trimethylbenzoyl-diphenyl-phosphine oxide, bis(2,4,6-trimethylbenzoyl)-phenyl-phosphine oxide, ethanone, 1-[9-ethyl-6-2(2-methylbenzoyl)-9H-carbazole-3-yl]-1-(O-acetyloxime), benzophenone, methyl o-benzoylbenzoate, 4,4′-bis(dimethylamino)benzophenone, 4,4′-bis(diethylamino)benzophenone, 4,4′-dichlorobenzophenone, 4-benzoyl-4′-methyldiphenylketone, dibenzylketone, fluorenone, 2,2′-diethoxyacetophenone, 2,2-dimethoxy-2-phenylacetophenone, 2-hydroxy-2-methylpropiophenone, p-t-butyldichloroacetophenone, thioxanthone, 2-methylthioxanthone, 2-chlorothioxanthone, 2-isopropylthioxanthone, diethylthioxanthone, benzyl, benzyl dimethyl ketal, benzyl-β-methoxyethylacetal, benzoin, benzoin methyl ether, benzoin butyl ether, anthraquinone, 2-t-butylanthraquinone, 2-amylanthraquinone, β-chloroanthraquinone, anthrone, benzanthrone, dibenzosuberone, methylene anthrone, 4-azidebenzalacetophenone, 2,6-bis(p-azidebenzylidene)cyclohexanone, 6-bis(p-azidebenzylidene)-4-methylcyclohexanone, 1-phenyl-1,2-butanedione-2-(o-methoxycarbonyl)oxime, 1-phenyl-propanedione-2-(o-ethoxycarbonyl)oxime, 1-phenyl-propanedione-2-(o-benzoyl)oxime, 1,3-diphenyl-propanetrione-2-(o-ethoxycarbonyl)oxime, 1-phenyl-3-ethoxy-propanetrione-2-(o-benzoyl)oxime, Michler's ketone, 2-methyl-[4-(methylthio)phenyl]-2-morpholino-1-propanone, naphthalenesulfonyl chloride, quinolinesulfonyl chloride, N-phenylthioacridone, 4,4′-azobisisobutyronitrile, diphenyl disulfide, benzothiazole disulfide, triphenylphosphine, camphor quinone, 2,4-diethylthioxanthone, isopropylthioxanthone, carbon tetrabromide, tribromophenylsulfone, benzoyl peroxide, and combinations of a photo-reductive pigment such as eosin and methylene blue, and a reducing agent such as ascorbic acid and triethanolamine.

The content of the (D) photopolymerization initiator based on 100 parts by mass of the (C) photosensitive component is preferably 0.05 to 30 parts by mass. When the content of the (D) photopolymerization initiator based on 100 parts by mass of the (C) photosensitive component is 0.05 parts by mass or more, the curing density of the exposed part increases, so that the residual film ratio after development can be increased. On the other hand, when the content of the (D) photopolymerization initiator is 30 parts by mass or less, excessive light absorption at the upper part of the coating film is suppressed, so that the conductive pattern can be inhibited from having a reversed tapered shape to suppress reduction in adhesion to the substrate.

The conductive paste of the present invention may contain a sensitizer together with the (D) photopolymerization initiator in order to improve the sensitivity.

Examples of the sensitizer include 2,4-diethylthioxanthone, isopropylthioxanthone, 2,3-bis(4-diethylaminobenzal)cyclopentanone, 2,6-bis(4-dimethylaminobenzal)cyclohexanone, 2,6-bis(4-dimethylaminobenzal)-4-methylcyclohexanone, Michler's ketone, 4,4-bis(diethylamino)benzophenone, 4,4-bis(dimethylamino)chalcone, 4,4-bis(diethylamino)chalcone, p-dimethylaminocinnamylideneindanone, p-dimethylaminobenzylideneindanone, 2-(p-dimethylaminophenylvinylene)isonaphthothiazole, 1,3-bis(4-dimethylaminophenylvinylene)isonaphthothiazole, 1,3-bis(4-dimethylaminobenzal)acetone, 1,3-carbonylbis(4-diethylaminobenzal)acetone, 3,3-carbonylbis(7-diethylaminocoumarin), N-phenyl-N-ethylethanolamine, N-phenylethanolamine, N-tolyldiethanolamine, isoamyl dimethylaminobenzoate, isoamyl diethylaminobenzoate, 3-phenyl-5-benzoylthiotetrazole, and 1-phenyl-5-ethoxycarbonylthiotetrazole.

The content of the sensitizer based on 100 parts by mass of the (C) photosensitive component is preferably 0.05 to 10 parts by mass. When the content of the sensitizer based on 100 parts by mass of the (C) photosensitive component is 0.05 parts by mass or more, the photosensitivity is sufficiently improved. On the other hand, when the content of the sensitizer is 10 parts by mass or less, excessive light absorption at the upper part of the coating film is suppressed, so that the conductive pattern can be inhibited from having a reversed tapered shape to suppress reduction in adhesion to the substrate.

The conductive paste of the present invention may contain a solvent. The solvent to be used may be appropriately determined according to solubility of the (C) photosensitive component contained in the conductive paste or a method for applying the conductive paste. Examples of the solvent include N,N-dimethylacetamide, N,N-dimethylformamide, N-methyl-2-pyrrolidone, dimethyl imidazolidinone, dimethyl sulfoxide, γ-butyrolactone, ethyl lactate, 1-methoxy-2-propanol, 1-ethoxy-2-propanol, ethylene glycol mono-n-propyl ether, diacetone alcohol, tetrahydrofurfuryl alcohol, diethylene glycol monoethyl ether acetate (hereinafter, referred to as “DMSA”) and propylene glycol monomethyl ether acetate.

The conductive paste of the present invention may contain additives such as a non-photosensitive polymer having no unsaturated double bond in the molecule, a plasticizer, a leveling agent, a surfactant, a silane coupling agent, a defoaming agent and a pigment as long as the desired characteristics of the conductive paste are not impaired. Examples of the non-photosensitive polymer include epoxy resins, novolak resins, phenol resins, polyimide precursors and pre-closed ring polyimides.

Examples of the plasticizer include dibutyl phthalate, dioctyl phthalate, polyethylene glycol, and glycerin. Examples of the leveling agent include special vinyl-based polymers and special acryl-based polymers. Examples of the silane coupling agent include methyltrimethoxysilane, dimethyldiethoxysilane, phenyltriethoxysilane, hexamethyldisilazane, 3-methacryloxypropyltrimethoxysilane, 3-glycidoxypropyltrimethoxysilane, and vinyltrimethoxysilane.

The conductive paste of the present invention can be prepared using, for example, a disperser or a kneader such as a three-roll mill, a ball mill, and a planetary ball mill.

A method for producing a conductive pattern according to the present invention includes: a coating step of applying the conductive paste of the present invention onto a substrate to obtain a coating film; a photolithography step of exposing and developing the coating film to obtain a pattern; and a curing step of heating the pattern at 100 to 300° C. to obtain a conductive pattern.

The coating step included in the method for producing a conductive pattern according to the present invention is a step of applying the conductive paste of the present invention onto a substrate to obtain a coating film.

Examples of the substrate to be coated with the conductive paste of the present invention include polyethylene terephthalate (PET) films, polyimide films, polyester films, aramid films, epoxy resin substrates, polyether imide resin substrates, polyether ketone resin substrates, polysulfone-based resin substrates, glass substrates, silicon wafers, alumina substrates, aluminum nitride substrates and silicon carbide substrates.

Examples of the method for applying the conductive paste of the present invention to the substrate include spin coating by a spinner, spray coating, roll coating, screen printing, and coating by a blade coater, a die coater, a calender coater, a meniscus coater, or a bar coater.

When the conductive paste of the present invention contains a solvent, the resulting coating film may be dried to remove the solvent. Examples of the method for drying the coating film include heating/drying by an oven, a hot plate or irradiation of an infrared ray, and vacuum drying. Generally, the heating/drying temperature is 50 to 80° C., and the heating/drying time is 1 minute to several hours.

The thickness of the coating film obtained in the coating step may be appropriately determined according to the coating method, the total solid concentration or viscosity of the conductive paste, or the like. The thickness of the coating film after drying is preferably 0.1 to 50 μm.

The photolithography step included in the method for producing a conductive pattern according to the present invention is a step of preparing a pattern by exposing and developing the coating film obtained in the coating step.

A light source to be used for exposure of the coating film is preferably an i ray (365 nm), an h ray (405 nm) or a g ray (436 nm) in a mercury lamp.

After exposure, the unexposed part is removed with a developer to obtain a desired pattern. Examples of the developer to be used for alkali development include aqueous solutions of tetramethylammonium hydroxide, diethanolamine, diethylaminoethanol, sodium hydroxide, potassium hydroxide, sodium carbonate, potassium carbonate, triethylamine, diethylamine, methylamine, dimethylamine, dimethylaminoethyl acetate, dimethylaminoethanol, dimethylaminoethyl methacrylate, cyclohexylamine, ethylenediamine, and hexamethylenediamine. To these aqueous solutions may be added a polar solvent such as N-methyl-2-pyrrolidone, N,N-dimethylformamide, N,N-dimethylacetamide, dimethyl sulfoxide, or γ-butyrolactone, an alcohol such as methanol, ethanol, or isopropanol, an ester such as ethyl lactate or propylene glycol monomethyl ether acetate, a ketone such as cyclopentanone, cyclohexanone, isobutyl ketone, or methyl isobutyl ketone, or a surfactant.

Examples of the developer to be used for organic development include polar solvents such as N-methyl-2-pyrrolidone, N-acetyl-2-pyrrolidone, N,N-dimethylacetamide, N,N-dimethylformamide, dimethyl sulfoxide, and hexamethylphosphortriamide, and mixed solutions of these polar solvents and methanol, ethanol, isopropyl alcohol, xylene, water, methyl carbitol or ethyl carbitol.

Examples of the development method include a method in which a developer is sprayed on a coating film surface while a substrate is left at rest or rotated, a method in which a substrate is immersed in a developer, and a method in which a base material is immersed in a developer while an ultrasonic wave is applied thereto.

The pattern obtained in the development step may be subjected to a rinsing treatment with a rinsing liquid. Here, examples of the rinsing liquid include water, and aqueous solutions obtained by adding to water an alcohol such as ethanol and isopropyl alcohol, or an ester such as ethyl lactate and propylene glycol monomethyl ether acetate.

The curing step included in the method for producing a conductive pattern according to the present invention is a step of preparing a conductive pattern by heating the pattern obtained in the photolithography step at 100 to 300° C. The curing refers to a heating method including intentionally leaving a resin component in a conductive pattern, and when the weight loss ratio of the conductive pattern after curing is 5% or less, sufficient adhesion with the substrate can be attained.

Examples of the curing method include heating/drying with an oven, an inert oven or a hot plate, heating/drying with an electromagnetic wave by an infrared heater or the like, and vacuum drying.

The curing temperature is required to be 100 to 300° C. The curing temperature is preferably 120 to 180° C. If the curing temperature is lower than 100° C., the volume shrinkage amount of the pattern does not increase, and the specific resistance of the resulting conductive pattern does not sufficiently decrease. On the other hand, if the curing temperature is higher than 300° C., a conductive pattern cannot be formed on a substrate etc. which has low heat resistance.

### EXAMPLES

Hereinafter, the present invention will be described in detail by way of examples and comparative examples. The aspects of the present invention are not limited to these examples.

Materials used in examples and comparative examples are as follows.

[(A) Metal Particles]

Silver particles having a volume average particle size as described in Tables 1 and 2.

[(B) Tin Compound]
SN-100P (antimony-doped tin oxide; manufactured by Ishihara Sangyo Kaisha, Ltd.)
T-1 (antimony-doped tin oxide; manufactured by Mitsubishi Materials Corporation)
FS-10P (antimony-doped tin oxide, acicular powder having an aspect ratio of 20 to 30; manufactured by Ishihara Sangyo Kaisha, Ltd.)
E-ITO (indium tin oxide; manufactured by Mitsubishi Materials Corporation)
SP-2 (phosphorus-doped tin oxide; manufactured by Mitsubishi Materials Corporation)
S-2000 (tin oxide; manufactured by Mitsubishi Materials Corporation)
ET-300 W (titanium oxide covered with antimony-doped tin oxide (antimony-doped tin oxide content: 18% by mass) manufactured by Ishihara Sangyo Kaisha, Ltd.)
ET-1000 (titanium oxide covered with antimony-doped tin oxide (antimony-doped tin oxide content: 15% by mass) manufactured by Ishihara Sangyo Kaisha, Ltd.)

[(C) Photosensitive Component]
LIGHT ACRYLATE BP-4EA (acryl-based monomer; manufactured by KYOEISHA CHEMICAL Co., LTD.)

### Synthesis Example 1

Addition reaction product of acryl-based copolymer of EA/2-ethylhexyl methacrylate (hereinafter, referred to as “2-EHMA”)/St/AA (copolymerization ratio (parts by mass): 20/40/20/15) with 5 parts by mass of glycidyl methacrylate (hereinafter, referred to as “GMA”)

In a reaction vessel in a nitrogen atmosphere, 150 g of DMEA was added and the temperature was elevated to 80° C. using an oil bath. To this was added dropwise for 1 hour a mixture including 20 g of EA, 40 g of 2-EHMA, 20 g of St, 15 g of AA, 0.8 g of 2,2′-azobisisobutyronitrile and 10 g of DMEA. After completion of the dropwise addition, a polymerization reaction was further carried out for 6 hours. Thereafter, 1 g of hydroquinone monomethyl ether was added to stop the polymerization reaction. Subsequently, a mixture including 5 g of GMA, 1 g of triethyl benzyl ammonium chloride and 10 g of DMEA was added dropwise for 0.5 hours. After completion of the dropwise addition, an addition reaction was further carried out for 2 hours. The obtained reaction solution was refined with methanol to remove unreacted impurities, and dried under vacuum for 24 hours to obtain an acryl-based copolymer (C-1). The obtained acryl-based copolymer (C-1) had an acid value of 103 mg KOH/g.

### Synthesis Example 2

Addition reaction product of acryl-based copolymer of ethylene oxide-modified bisphenol A diacrylate (FA-324A; manufactured by Hitachi Chemical Company, Ltd.)/EA/AA (copolymerization ratio (parts by mass): 50/10/15) with 5 parts by mass of GMA

In a reaction vessel in a nitrogen atmosphere, 150 g of DMEA was added and the temperature was elevated to 80° C. using an oil bath. To this was added dropwise for 1 hour a mixture including 50 g of ethylene oxide modified bisphenol A diacrylate FA-324A, 20 g of EA, 15 g of AA, 0.8 g of 2,2′-azobisisobutyronitrile and 10 g of DMEA. After completion of the dropwise addition, a polymerization reaction was further carried out for 6 hours. Thereafter, 1 g of hydroquinone monomethyl ether was added to stop the polymerization reaction. Subsequently, a mixture including 5 g of GMA, 1 g of triethyl benzyl ammonium chloride and 10 g of DMEA was added dropwise for 0.5 hours. After completion of the dropwise addition, an addition reaction was further carried out for 2 hours. The obtained reaction solution was refined with methanol to remove unreacted impurities, and dried under vacuum for 24 hours to obtain an acryl-based copolymer (C-2). The obtained acryl-based copolymer (C-2) had an acid value of 96 mg KOH/g.

### Synthesis Example 3

Acryl-based copolymer of EA/2-EHMA/BA/N-methylol acrylamide/AA (copolymerization ratio (parts by mass): 20/40/20/5/15)

In a reaction vessel in a nitrogen atmosphere, 150 g of DMEA was added and the temperature was elevated to 80° C. using an oil bath. To this was added dropwise for 1 hour a mixture including 20 g of EA, 40 g of 2-EHMA, 20 g of BA, 5 g of N-methylol acrylamide, 15 g of AA, 0.8 g of 2,2′-azobisisobutyronitrile and 10 g of DMEA. After completion of the dropwise addition, a polymerization reaction was further carried out for 6 hours. Thereafter, 1 g of hydroquinone monomethyl ether was added to stop the polymerization reaction. The obtained reaction solution was refined with methanol to remove unreacted impurities, and dried under vacuum for 24 hours to obtain an acryl-based copolymer (C-3). The obtained acryl-based copolymer (C-3) had an acid value of 103 mg KOH/g.

[(D) Photopolymerization Initiator]
IRGACURE 369 (manufactured by Ciba Japan K.K.)

[Solvent]

DMEA (manufactured by Tokyo Chemical Industry Co., Ltd.)

### Example 1

In a 100 mL clean bottle, 10.0 g of the acryl-based copolymer (C-1), 2.0 g of LIGHT ACRYLATE BP-4EA, 0.60 g of IRGACURE 369 and 6.0 g of DMEA were added and mixed by “Awatori Rentaro” (registered trademark) (ARE-310; manufactured by THINKY CORPORATION) to obtain 18.6 g of a resin solution (total solid content: 67.7% by mass).

The obtained resin solution (10.0 g), Ag particles (33.9 g) (volume average particle size: 0.5 μm) and E-ITO (4.5 g) were mixed together, and kneaded using a three-roll mill (EXAKT M-50; manufactured by EXAKT) to obtain a conductive paste 1 (48.4 g). The obtained conductive paste 1 was evaluated as follows.

<Evaluation of Patterning Property>

The conductive paste 1 was applied onto a 100 μm-thick PET film by a screen printing method in such a manner that the coating thickness after drying was as shown in Table 3, and the obtained coating film was dried in a drying oven at 100° C. for 10 minutes. The dried film was exposed via a photomask having three units having different L/S values, with one unit including a group of lines arranged with a fixed line-and-space (hereinafter, referred to as L/S), namely a light-transmissive pattern, and developed to obtain three patterns having different L/S values. Thereafter, the obtained three patterns were cured in a drying oven at 140° C. for 1 hour to obtain three conductive patterns having different L/S values. The L/S values of the units of the photomask were set to 20/20, 15/15 and 10/10 (each showing a line width (μm)/interval (μm)). The obtained conductive patterns were observed with an optical microscope to confirm a pattern which was free from residues between patterns and free from pattern peeling and had the smallest L/S value. A sample was rated S when the L/S value was 10/10, a sample was rated A when the L/S value was 15/15, a sample was rated B when the L/S value was 20/20, and a sample was rated C when the L/S value was 20/20, and it was unable to form a conductive pattern. The evaluation results are shown in Table 3. Exposure was performed over the entire line at an exposure amount of 200 mJ/cm² (in terms of a wavelength of 365 nm) using exposure equipment (PEM-6M manufactured by UNION OPTICAL Colo., LTD.), and development was performed by immersing a substrate in a 0.25 wt % Na₂CO₃ solution for 30 seconds, and then subjecting the substrate to a rinsing treatment with ultrapure water.

<Evaluation of Specific Resistivity>

The conductive paste 1 was applied onto a 100 μm-thick PET film by a screen printing method in such a manner that the coating thickness after drying was as shown in Table 3, and the obtained coating film was dried in a drying oven at 100° C. for 10 minutes. The coating film after drying was exposed through a photomask having 100 light-transmissive patterns 106 as shown in FIG. 3, and was developed to obtain a pattern. Thereafter, the obtained pattern was cured in a drying oven at 140° C. for 1 hour to obtain a conductive pattern for measurement of a specific resistivity. The obtained conductive pattern had a line width of 0.40 mm and a line length of 80 mm. Conditions for exposure and development were the same as those in the method for evaluation of patterning characteristics.

To each of the ends of the obtained conductive pattern for measurement of a resistivity, an ohmmeter (RM 3544; manufactured by HIOKI E.E. CORPORATION) was connected to measure a resistance value, and a resistivity was calculated in accordance with the following formula (1). The film thickness can be measured using a probe type step profiler such as SURFCOM (registered trademark) 1400 (manufactured by TOKYO SEIMITSU CO., LTD.). More specifically, the film thickness can be calculated in the following manner: the film thickness is measured at each of randomly selected ten positions using a probe type step profiler (measurement length: 1 mm; scanning speed: 0.3 mm/sec), and an average value thereof is determined. In addition, the line width can be calculated in the following manner: the line width at each of randomly selected ten positions is observed with an optical microscope, analyzing the image data, and an average value thereof is determined.

Specific resistivity=resistance value×thickness×line width/line length (1)

For each of the resulting 100 conductive patterns for measurement of a specific resistivity, the specific resistivity was calculated, and a sample was rated C when 10% or more of the 100 conductive patterns showed a specific resistivity that did not fall within a range of average value±20%. For other cases, a sample was rated S when the average value was less than 100 μΩ·cm, a sample was rated A when the average value was 100 μΩ·cm or more and less than 150 μΩ·cm, a sample was rated B when the average value was 150 μΩ·cm or more and less than 200 μΩ·cm, and a sample was rated C when the average value was 200 μΩ·cm or more. The evaluation results are shown in Table 3.

<Evaluation of Contact Resistance Value>

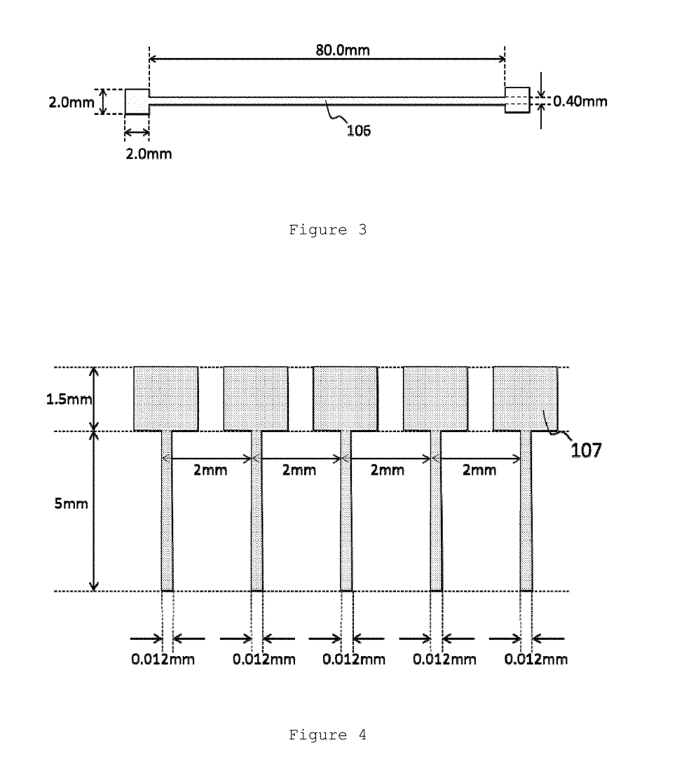

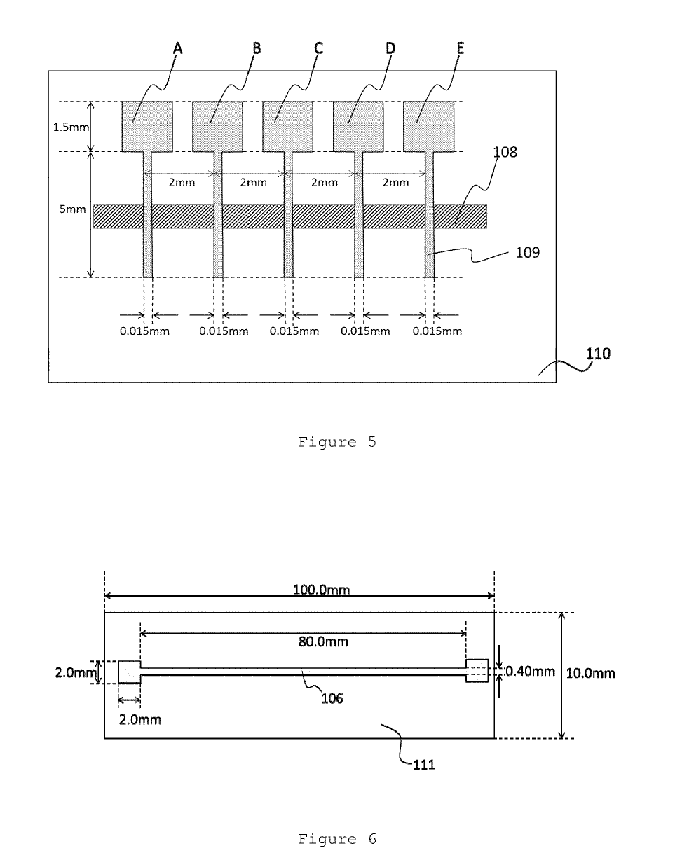

The conductive paste 1 was applied onto a 100 μm-thick PET film, on which ITO (indium tin oxide) was patterned in the form of a belt with widths of 50 μm, 100 μm and 200 μm, by a screen printing method in such a manner that the coating thickness after drying was as shown in Table 3, and the obtained coating film was dried in a drying oven at 100° C. for 10 minutes. The coating film after drying was exposed through a photomask having a light-transmissive pattern 107 as shown in FIG. 4, and was developed to obtain a pattern. Thereafter, the obtained pattern was cured in a drying oven at 140° C. for 1 hour to obtain a member for measurement of a contact resistance value in which an ITO pattern 108 and conductive patterns 109 were formed on a substrate 110, as shown in FIG. 5. Conditions for exposure and development were the same as those in the method for evaluation of patterning characteristics.

The obtained conductive patterns 109 each had a line width of 15 μm. Resistance values between terminal portions A and B, between terminal portions A and C, between terminal portions A and D and between terminal portions A and E of the conductive pattern 109 were each measured by an ohmmeter (RM 3544; manufactured by HIOKI E.E. CORPORATION), and a contact resistance was calculated by a TLM (transmission line model) method. For each of the resulting 100 conductive patterns 109, a contact resistance was calculated, and a sample was rated C when 10% or more of the 100 conductive patterns showed a specific resistivity that did not fall within a range of average value±20%. For other cases, a sample was rated S when the average value was 1.5 kΩ or less.

For samples to which any of S and C was not applicable, a member for measurement of a contact resistance value was obtained using a PET film on which ITO was patterned in the form of a belt with a width of 100 μm, and a contact resistance was calculated in the same manner as described above. A sample was rated C when 10% or more of the 100 conductive patterns showed a specific resistivity that did not fall within a range of average value±20%, and for other cases, a sample was rated A when the average value was 1.5 kΩ or less.

For samples to which any of S, A and C was applicable, a member for measurement of a contact resistance value was obtained using a PET film on which ITO was patterned in the form of a belt with a width of 200 μm, and a contact resistance was calculated in the same manner as described above. A sample was rated C when 10% or more of the 100 conductive patterns showed a specific resistivity that did not fall within a range of average value±20%, and for other cases, a sample was rated B when the average value was 1.5 kΩ or less, and a sample was rated C when the average value was more than 1.5 kΩ. The evaluation results are shown in Table 3.

<Evaluation of Flexibility>

A member shown in FIG. 6 in which a conductive pattern was formed in the same manner as in evaluation for measurement of a specific resistivity was provided, and a resistance value of a conductive pattern 106 was measured by an ohmmeter. Thereafter, a bending operation of bending the member to an angle of 180 degrees with a curvature radius of 5 mm, and then returning the member to the original position was repeatedly carried out 1000 times in such a manner that the conductive pattern 106 was situated inside, outside, inside . . . alternately, the resistance value was then measured again, and a resistance value change ratio (%) was calculated. A sample was rated A when the resistance value change ratio was 20% or less, and cracking, peeling and breakage did not occur in the conductive pattern 106, and in other cases, a sample was rated C. The evaluation results are shown in Table 3.

### Examples 2 to 26

Conductive pastes having compositions as shown in Table 1 or 2 were produced in the same manner as in Example 1, and were evaluated in the same manner as in Example 1. The evaluation results are shown in Table 3.

### Comparative Examples 1 to 7

Conductive pastes having compositions as shown in Table 2 were produced in the same manner as in Example 1, and were evaluated in the same manner as in Example 1. A sample rated C in evaluation of patterning property was not evaluated for other properties. The evaluation results are shown in Table 3.

TABLE 1

| | | | | | | (C) Photosensitive component | | | | |
|---|---|---|---|---|---|---|---|---|---|---|
| | | | | | | | | Acryl-based | (D) | Solvent |
| | (A) Metal | | | | | | | monomer | Photopolymerization | <CA> |
| | particles | | | | | | | <BP-4EA> | initiator | Addition amount |
| | <Ag> | | (B) Tin compound | | | Acryl-based | | Addition amount | <IRGACURE 369> | based on |
| | Volume | Ratio to | | Volume | Ratio to | copolymer | | based on 100 parts | Addition amount based | 100 parts |
| | average | total | | average | total | | Addition | by mass of | on 100 parts by mass of | by mass of (C) |
| | particle | solid | | particle | solid | | amount | acryl-based | (C) photosensitive | photosensitive |
| | size | (% by | | size | (% by | | (parts by | copolymer | component | component |
| | (μm) | mass) | Type | (μm) | mass) | Type | mass) | (parts by mass) | (parts by mass) | (parts by mass) |
| Example 1 | 0.5 | 75 | E-ITO | 0.06 | 10 | C-1 | 100 | 20 | 5 | 50 |
| Example 2 | 0.1 | 75 | E-ITO | 0.06 | 10 | C-1 | 100 | 20 | 5 | 50 |
| Example 3 | 1.0 | 75 | E-ITO | 0.06 | 10 | C-1 | 100 | 20 | 5 | 50 |
| Example 4 | 3.0 | 75 | E-ITO | 0.06 | 10 | C-1 | 100 | 20 | 5 | 50 |
| Example 5 | 0.5 | 75 | E-ITO | 0.06 | 10 | C-1 | 100 | 20 | 5 | 50 |
| Example 6 | 0.5 | 85 | E-ITO | 0.06 | 2 | C-1 | 100 | 20 | 5 | 50 |
| Example 7 | 0.5 | 65 | E-ITO | 0.06 | 20 | C-1 | 100 | 20 | 5 | 50 |
| Example 8 | 0.5 | 70 | E-ITO | 0.06 | 15 | C-1 | 100 | 20 | 5 | 50 |
| Example 9 | 0.5 | 80 | E-ITO | 0.06 | 5 | C-1 | 100 | 20 | 5 | 50 |
| Example 10 | 0.5 | 75 | FS-10P | 0.09 | 10 | C-1 | 100 | 20 | 5 | 50 |
| Example 11 | 0.5 | 80 | FS-10P | 0.09 | 5 | C-1 | 100 | 20 | 5 | 50 |
| Example 12 | 0.5 | 65 | FS-10P | 0.09 | 20 | C-1 | 100 | 20 | 5 | 50 |
| Example 13 | 0.5 | 75 | SN-100P | 0.06 | 10 | C-1 | 100 | 20 | 5 | 50 |
| Example 14 | 0.5 | 80 | SN-100P | 0.06 | 5 | C-1 | 100 | 20 | 5 | 50 |
| Example 15 | 0.5 | 65 | SN-100P | 0.06 | 20 | C-1 | 100 | 20 | 5 | 50 |
| Example 16 | 0.5 | 70 | SN-100P | 0.06 | 15 | C-1 | 100 | 20 | 5 | 50 |
| Example 17 | 0.5 | 75 | SP-2 | 0.03 | 10 | C-1 | 100 | 20 | 5 | 50 |
| Example 18 | 0.5 | 80 | SP-2 | 0.03 | 5 | C-1 | 100 | 20 | 5 | 50 |

TABLE 2

| | | | | | | | (C) Photosensitive component | | | (D) | |
|---|---|---|---|---|---|---|---|---|---|---|---|
| | | | | | | | | | Acryl-based | Photopolymerization | Solvent |
| | | | | | | | | | monomer | initiator | <CA> |
| | (A) Metal | | (B) Tin compound | | | | | | <BP-4EA> | <IRGACURE 369> | Addition |
| | particles | | | | | Ratio of | | | Addition | Addition amount | amount |
| | <Ag> | | | | Ratio of | tin | Acryl-based | | amount based | based on | based on |
| | Volume | Ratio to | | Volume | particles | compound | copolymer | | on 100 parts by | 100 parts | 100 parts |
| | average | total | | average | to total | to total | | Addition | mass of | by mass of (C) | by mass of (C) |
| | particle | solid | | particle | solid | solid | | amount | acryl-based | photosensitive | photosensitive |
| | size | (% by | | size | (% by | (% by | | (parts by | copolymer | component | component |
| | (μm) | mass) | Type | (μm) | mass) | mass) | Type | mass) | (parts by mass) | (parts by mass) | (parts by mass) |
| Example 19 | 0.5 | 65 | SP-2 | 0.03 | 20 | 20 | C-1 | 100 | 20 | 5 | 50 |
| Example 20 | 0.5 | 75 | S-2000 | 0.04 | 10 | 10 | C-1 | 100 | 20 | 5 | 50 |
| Example 21 | 0.5 | 80 | S-2000 | 0.04 | 5 | 5 | C-1 | 100 | 20 | 5 | 50 |
| Example 22 | 0.5 | 65 | S-2000 | 0.04 | 20 | 20 | C-1 | 100 | 20 | 5 | 50 |
| Example 23 | 0.5 | 75 | T-1 | 0.05 | 10 | 10 | C-1 | 100 | 20 | 5 | 50 |
| Example 24 | 0.5 | 75 | E-ITO | 0.06 | 10 | 10 | C-1 | 100 | 20 | 5 | 50 |
| Example 25 | 0.5 | 75 | E-ITO | 0.06 | 10 | 10 | C-2 | 100 | — | 5 | 50 |
| Example 26 | 0.5 | 75 | E-ITO | 0.06 | 10 | 10 | C-3 | 100 | 20 | 5 | 50 |
| Comparative | 0.5 | 60 | E-ITO | 0.06 | 25 | 25 | C-1 | 100 | 20 | 5 | 50 |
| Example 1 | | | | | | | | | | | |
| Comparative | 0.5 | 65 | E-ITO | 0.06 | 25 | 25 | C-1 | 100 | 20 | 5 | 50 |
| Example 2 | | | | | | | | | | | |
| Comparative | 0.5 | 85 | E-ITO | 0.06 | 1.5 | 1.5 | C-1 | 100 | 20 | 5 | 50 |
| Example 3 | | | | | | | | | | | |
| Comparative | 0.5 | 80 | ET300W | 0.08 | 1.5 | 0.3 | C-1 | 100 | 20 | 5 | 50 |
| Example 4 | | | | | | | | | | | |
| Comparative | 0.5 | 70 | ET300W | 0.08 | 10 | 1.8 | C-1 | 100 | 20 | 5 | 50 |
| Example 5 | | | | | | | | | | | |
| Comparative | 0.5 | 85 | FT-1000 | 0.2 | 1.5 | 0.2 | C-1 | 100 | 20 | 5 | 50 |
| Example 6 | | | | | | | | | | | |
| Comparative | 0.5 | 75 | FT-1000 | 0.2 | 10 | 1.5 | C-1 | 100 | 20 | 5 | 50 |
| Example 7 | | | | | | | | | | | |

TABLE 3

| | Coating film thickness | | | Contact | |
|---|---|---|---|---|---|
| | for evaluation of | Pattern- | Specific | resis- | |
| | patterning property | ing | resis- | tance | Flexi- |
| | (after drying; μm) | property | tivity | value | bility |
| Example 1 | 2 | S | S | S | S |
| Example 2 | 1 | S | A | S | S |
| Example 3 | 3 | A | A | S | S |
| Example 4 | 10 | B | A | S | A |
| Example 5 | 2 | S | A | S | S |
| Example 6 | 2 | A | S | B | S |
| Example 7 | 2 | A | B | S | A |
| Example 8 | 2 | S | S | S | S |
| Example 9 | 2 | A | S | A | S |
| Example 10 | 2 | A | A | A | S |
| Example 11 | 2 | A | S | B | S |
| Example 12 | 2 | A | B | S | A |
| Example 13 | 2 | S | S | A | S |
| Example 14 | 2 | S | S | B | S |
| Example 15 | 2 | A | B | S | A |
| Example 16 | 2 | A | A | S | S |
| Example 17 | 2 | A | A | B | S |
| Example 18 | 2 | A | S | B | S |
| Example 19 | 2 | A | B | A | A |
| Example 20 | 2 | S | A | B | S |
| Example 21 | 2 | S | A | B | S |
| Example 22 | 2 | A | B | A | S |
| Example 23 | 2 | S | A | A | S |
| Example 24 | 2 | S | S | S | S |
| Example 25 | 2 | B | S | S | B |
| Example 26 | 2 | B | S | S | B |
| Comparative | 2 | A | C | S | B |
| Example 1 | | | | | |
| Comparative | 2 | C | — | — | — |
| Example 2 | | | | | |
| Comparative | 2 | S | S | C | S |
| Example 3 | | | | | |
| Comparative | 2 | A | A | C | B |
| Example 4 | | | | | |
| Comparative | 2 | C | — | — | — |
| Example 5 | | | | | |
| Comparative | 2 | S | S | C | S |
| Example 6 | | | | | |
| Comparative | 2 | C | — | — | — |
| Example 7 | | | | | |

### DESCRIPTION OF REFERENCE SIGNS

100: Substrate
101: Transparent electrode pattern
102: Transparent electrode pattern
103: Insulating material
104: Bridge pattern
105: Routing wiring
106: Light-transmissive pattern
107: Light-transmissive pattern
108: ITO pattern
109: Conductive pattern
110: PET film
111: PET film

1. A conductive paste comprising:
(A) metal particles;
(B) a tin compound;
(C) a photosensitive component; and
(D) a photopolymerization initiator,
wherein
the (B) tin compound is selected from the group consisting of indium tin oxide, antimony-doped tin oxide, phosphorus-doped tin oxide, fluorine-doped tin oxide and tin oxide, and
a ratio of the (B) tin compound to a total solid is 2 to 20% by mass.

2. The conductive paste according to claim 1, wherein the (B) tin compound is indium tin oxide.

3. The conductive paste according to claim 1, wherein the (A) metal particles have a volume average particle size of 0.1 to 3.0 μm.

4. The conductive paste according to claim 1, wherein the (B) tin compound has a volume average particle size of 0.01 to 0.3 μm.

5. The conductive paste according to claim 1, wherein a ratio of the (A) metal particles to the total solid is 60 to 85% by mass.

6. The conductive paste according to claim 1, wherein the (A) metal particles are particles of metal selected from the group consisting of gold, silver and copper.

7. A touch sensor member comprising
a transparent electrode pattern, and
a conductive pattern formed using the conductive paste according to claim 1.

8. The touch sensor member according to claim 7, wherein the transparent electrode pattern is formed by combining a plurality of mutually independent transparent electrode patterns, and the plurality of transparent electrode patterns are connected by the conductive pattern.

9. A method for producing a conductive pattern, the method comprising:
a coating step of applying the conductive paste according to claim 1 onto a substrate to obtain a coating film;
a photolithography step of exposing and developing the coating film to obtain a pattern; and
a curing step of heating the pattern at 100 to 300° C. to obtain a conductive pattern.
